(19) United States
(12) Patent Application Publication
(10) Pub. No.: US 2015/0075594 A1
(43) Pub. Date: Mar. 19, 2015

(54) W18O49-TYPE TUNGSTEN OXIDE NANOMATERIAL AND APPLICATIONS THEREOF IN LIGHT SENSOR, MOSFET AND SOLAR CELL

(71) Applicant: National Tsing Hua University, Hsinchu (TW)

(72) Inventors: Tri-Rung YEW, Hsinchu (TW); Yu-Ming HSU, Hsinchu (TW)

(73) Assignee: National Tsing Hua University, Hsinchu (TW)

(21) Appl. No.: 14/158,694

(22) Filed: Jan. 17, 2014

(30) Foreign Application Priority Data
Sep. 17, 2013 (TW) 102133608

(51) Int. Cl. H01L 29/26; H01L 31/032

(52) U.S. Cl. CPC H01L 29/26; H01L 31/0321
USPC 136/255; 257/43; 252/519.14

(57) ABSTRACT

The invention proposes W₁₈O₄₉-type tungsten oxide nanomaterial, which is fabricated with a precursor comprising WS₂ and formed by thermal oxidation from the precursor. Applications using W₁₈O₄₉-type tungsten oxide nanomaterial in light sensor, MOSFET and solar cell, are also disclosed.

### BACKGROUND OF THE INVENTION

1. Field of the Invention

The present invention relates to a tungsten oxide nanomaterial, and more particularly, to a sulfur-doped W₁₈O₄₉-type tungsten oxide nanomaterial and applications thereof.

2. Description of the Prior Art

Tungsten oxide (WOₓ) is a metal oxide with photoconductivity as well as a semiconductor. With the exciting of the photo energy, the valence electron can transit to the conduction band resulted in generating light current, and therefore can be applied as the light sensor. The tungsten oxide material is also characterized in gas absorption, and its resistance may change corresponding to gas absorption or desorption. Therefore, detecting the change of the resistance of the tungsten oxide material can be applied for gas detection.

The conventional WO₃ is a canary yellow rhomboidal crystal in the room temperature, and has about 2.6 eV band gap. Light sensors or gas detectors made of tungsten oxide nanomaterial semiconductor material have increased surface-to-volume ratio in terms of enhanced surface activity, photoconductivity gain, detector sensitivity or improved reaction time of detecting gas. The tungsten oxide material reveals characteristics of semiconductor, and can be also applied as MOSFET (metal-oxide-semiconductor field-effect transistor) material. For example, WO₃ Nanowires on Carbon Papers: Electronic Transport, Improved Ultraviolet-light Photo detectors and Excellent Field Emitters (Liang Li, Yong Zhang et al., on J. Mater. Chem., 2011, 21, 6525-6530), Ultraviolet Photoconductance of a Single Hexagonal WO₃ Nanowire, by Kai Huang, Qing Zhang et al, published on Nano. Res. (2010) 3:281-287.

Since tungsten oxide nanomaterial can be applied to the detector, MOSFET and photoconductive devices, it's an important goal to increase the surface-to-volume ratio, and improve the sensitivity and photoconductivity gain so as to improve the photovoltaic efficiency.

### SUMMARY OF THE INVENTION

In one embodiment of the present invention, a sulfur-doped W₁₈O₄₉-type tungsten oxide nanomaterial is represented by a chemical formula (I): W₁₈O₍₄₉₋ₓ₎Sₓ . . . (I), wherein x ranges from 0.5 to 5.5. The W₁₈O₄₉-type tungsten oxide nanomaterial of the present invention utilizes a precursor containing WS₂, and fabricated by a deposition process after a thermal oxidation reaction.

In another embodiment of the present invention, a light sensor comprises a substrate, an electrode unit, a photoelectric conversion unit, and a current detecting unit. The electrode unit is configured on the substrate and has a first electrode and a second electrode. The photoelectric conversion unit is configured on the substrate, electrically connected to the first electrode and the second electrode. The photoelectric conversion unit comprises the sulfur-doped W₁₈O₄₉-type tungsten oxide nanomaterial. The photoelectric conversion unit is illuminated by a light to generate light current. The current detecting unit is electrically connected to the first electrode and the second electrode and configured for detecting the light current passing through the first electrode and the second electrode.

In yet another embodiment of the present invention, a metal-oxide-semiconductor field-effect transistor comprises a substrate, an oxide layer, a source/drain electrode, a semiconductor channel layer, and a gate electrode. The oxide layer is formed on the substrate, and the source/drain electrode is formed on the oxide layer. The semiconductor channel layer is configured on the oxide layer and a channel is formed between the source/drain electrodes. The channel comprises the sulfur-doped W₁₈O₄₉-type tungsten oxide nanomaterial. The gate electrode is configured on the lower surface of the substrate.

In still another embodiment of the present invention, a solar cell comprises a first substrate, a second substrate, a light absorption layer, and an n-type semiconductor layer. The first substrate has a first electrode, and the second substrate has a second electrode. The light absorption layer is located between the first substrate and the second substrate, wherein the light absorption layer comprises the sulfur-doped W₁₈O₄₉-type tungsten oxide nanomaterial. The n-type semiconductor layer is located between the light absorption layer and the second substrate.

The sulfur-doped W₁₈O₄₉-type tungsten oxide nanomaterial of the present invention is a new semiconductor material that dopes the sulfur to increase the light absorption rate and spectrum. The light absorbing wavelength is between 300-1400 nm, and the light absorption efficiency is about 80%. The band gap is modulated and reduced to 1.7 eV by doping the sulfur, and the lower band gap may improve the photoconductivity gain. The W₁₈O₄₉-type tungsten oxide material has the characteristics of photoconductivity as well as gas absorption so as to be applied in light/gas detectors, MOSFET and solar cell to improve the sensitivity and power conversion efficiency.

Other advantages of the present invention will become apparent from the following descriptions taken in conjunction with the accompanying drawings wherein certain embodiments of the present invention are set forth by way of illustration and examples.

### BRIEF DESCRIPTION OF THE DRAWINGS

The foregoing aspects and many of the accompanying advantages of this invention will become more readily appreciated as the same becomes better understood by reference to the following detailed descriptions, when taken in conjunction with the accompanying drawings, wherein:

FIG. 1a is a schematic diagram showing the process flow for fabricating the W₁₈O₍₄₉₋ₓ₎Sₓ nanomaterial according to one embodiment of the present invention;

FIG. 1b is a schematic diagram showing the W₁₈O₍₄₉₋ₓ₎Sₓ nanomaterial formed on the substrate according to one embodiment of the present invention;

FIG. 1c is an X-ray diffraction pattern of the W₁₈O₍₄₉₋ₓ₎Sₓ nanomaterial of the present invention;

FIG. 1d is an absorption spectrum of the W₁₈O₍₄₉₋ₓ₎Sₓ nanowire of the present invention;

FIG. 2a is a scanning electron microscope (SEM) image showing the W₁₈O₍₄₉₋ₓ₎Sₓ nanostructure of the present invention, using a precursor containing 100% WS₂;

FIG. 2b is a scanning electron microscope (SEM) image showing the W₁₈O₍₄₉₋ₓ₎Sₓ nanostructure of the present invention, using a precursor containing 66.7% WS₂;

FIG. 2c is a scanning electron microscope (SEM) image showing the W₁₈O₍₄₉₋ₓ₎Sₓ nanostructure of the present invention, using a precursor containing 40% WS₂;

FIG. 2d is a scanning electron microscope (SEM) image showing the W₁₈O₍₄₉₋ₓ₎Sₓ nanostructure of the present invention, using a precursor containing 10% WS₂;

FIG. 3a is a diagram showing (αhv)²-band gap value of the W₁₈O_{45.96}S_{3.04} nanowire of the present invention;

FIG. 3b is a diagram showing (αhv)²-band gap value of the W₁₈O_{47.63}S_{1.37} nanowire of the present invention;

FIG. 4a is a schematic diagram showing a light sensor according to one embodiment of the present invention;

FIG. 4b is a diagram showing the relation of light intensity and light current when illuminating the photoelectric conversion unit in the light sensor according to one embodiment of the present invention;

FIG. 5a is a schematic diagram showing a MOSFET according to one embodiment of the present invention;

FIG. 5b is a diagram showing the relation of I_{ds}-V_{g} measured in the MOSFET according to one embodiment of the present invention; and

FIG. 6 is a schematic diagram showing a solar cell according to one embodiment of the present invention.

### DESCRIPTION OF THE PREFERRED EMBODIMENT

The present invention is directed to providing a sulfur-doped W₁₈O₄₉-type tungsten oxide nanomaterial having the chemical formula (I):

W¹⁸O₍₄₉₋ₓ₎Sₓ . . . (I), wherein x ranges from 0.5 to 5.5, and x ranges from 2 to 4, preferably.

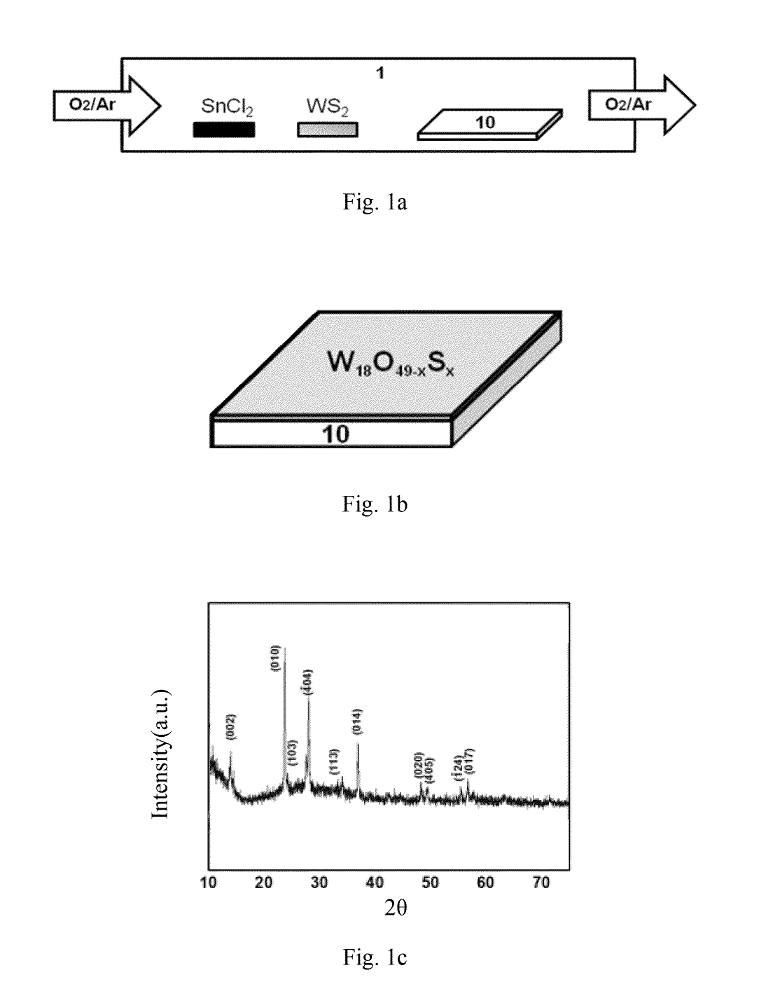

The sulfur-doped W₁₈O₄₉-type tungsten oxide (hereinafter abbreviated as W₁₈O₍₄₉₋ₓ₎Sₓ) nanomaterial of the present invention utilizes a precursor comprising WS₂, and is fabricated by a deposition process after a thermal oxidation reaction. As shown in FIG. 1a, a precursor containing WS₂ is put in the chamber 1. O₂ and Ar are put into the chamber 1 where O₂ is the reaction gas and Ar is the carrier gas. The chamber 1 is heated to a conditional temperature 400-1200° C., and then the O₂/Ar gas carries the precursor vapor and the reactant to the substrate 10 to form the sulfur-doped W₁₈O₄₉-type tungsten oxide nanomaterial to be deposited on the substrate 10.

The precursor may also comprise other reductants such as SnCl₂, and the doped ratio of sulfur in the W₁₈O₄₉-type tungsten oxide nanomaterial may be adjusted with the SnCl₂/WS₂ ratio in the precursor. During the process, WS₂ is oxidized to WO₃, and partial WO₃ is reduced to WO₂ by Sn²⁺ from SnCl₂, wherein W₁₈O₄₉ composed of WO₂ and WO₃ is formed on the substrate 10 and prevents from over-oxidization. When operated in the same process conditions (temperature, pressure and O₂ flow rate), the higher ratio of WS₂ in the precursor (in terms of lower SnCl₂), the more sulfur doped in the W₁₈O₄₉-type tungsten oxide. The X in the W₁₈O₍₄₉₋ₓ₎Sₓ may reach 5.5 for the highest value. In a preferred embodiment, the WS₂ ratio in the precursor is 20-80% and the x of the fabricated W₁₈O₍₄₉₋ₓ₎Sₓ may range from 2 to 4. Besides, factors such as the temperature, pressure and O₂ flow rate may also be operated to adjust the doped ratio of sulfur.

In the above-mentioned process, the precursor is mainly composed of SnCl₂ and WS₂. Here, it is known that the sulfur is a VI element and accordingly, the precursor may also contain other the chemical compounds having other VI elements (such as Se or Te), such as WSe₂ or WTe₂. In the above-mentioned process, partial O in W₁₈O₄₉ may be replaced by Se or Te in the precursor comprising WSe₂ or WTe₂ in the thermal oxidation reaction so as to fabricate W₁₈O₍₄₉₋ₓ₎Sₓ nanomaterials doped with Se or Te, in addition to sulfur.

The sulfur-doped W₁₈O₄₉ fabricated in the present invention is blue in color and the chemical formula is W₁₈O₄₉₋ₓSₓ. The doped ratio of sulfur in W₁₈O₍₄₉₋ₓ₎Sₓ may be determined by process parameters such as chamber temperature (high temperature area), the substrate temperature (low temperature area), ratio of the precursor (SnCl₂ and WS₂), and gas flow rate (O₂ and Ar). For example, when the substrate temperature is raised to 500, the W₁₈O₄₉₋ₓSₓ formed on the substrate is determined to be W₁₈O_{45.96}S_{3.04} based on quantitative chemical composition analysis. When the substrate temperature is raised to 600° C., the W₁₈O₄₉₋ₓSₓ formed on the substrate is W₁₈O_{47.63}S_{1.37}.

Among the process parameters mentioned above, the structure and morphology of the W₁₈O₄₉-type tungsten oxide may be affected by the ratio of WS₂ in the precursor and the substrate temperature, and the different types of nanomaterials such as nanowire, nanorod, nanotube or thin film structure may be formed specifically by adopting different parameters such as composition ratio of the precursor and substrate temperature.

The first embodiment of the present invention utilizes the chemical vapor deposition (CVD) process to fabricate the sulfur-doped W₁₈O₄₉-type tungsten oxide nanomaterial. As shown in FIG. 1a, first, the WS₂ and SnCl₂ powder are placed in the high temperature area of the chamber as a precursor, the ratio of WS₂ in the precursor is 20-80% and the temperature is 600-1200° C. to obtain the vapor. The substrate 10 is placed in the low temperature area of the chamber, and the temperature is controlled to 300-700° C. Then, trace amount of O₂ is put into the chamber 1 and the Ar is used as the carrier gas, the gas flow rate is 10 sccm (standard-state cubic centimeter per minute), and the pressure in the chamber 1 is about 0.1-1 Torr. When the substrate temperature is raised to 300-700° C., the substrate temperature is maintained for 1 hour and then cooled down to the room temperature. During the cooling process, as shown in FIG. 1b, the W₁₈O₍₄₉₋ₓ₎Sₓ nanomaterial grows on the substrate 10.

FIG. 1c is an X-ray diffraction pattern of the W₁₈O₍₄₉₋ₓ₎Sₓ nanomaterial fabricated according to the first embodiment of the present invention. The diffraction peak in the FIG. 1c is compared to the JCPDS database (Joint Committee on Powder Diffraction Standards), and the corresponding 2θ substantially matches that of the W₁₈O₄₉ lattice plane in the database No. 71-2450. Three main diffraction peaks match to the corresponding lattice planes (010), ( 4̅04) and (014). In the JCPDS database, the W₁₈O₄₉ in database No. 71-2450 is a monoclinic structure, and the lattice constant a=18.334 Å, b=3.786 Å, c=14.044 Å, and β=115.20°. Therefore, the lattice plane of the nanomaterial of the present invention matches the lattice plane in the database No. 71-2450 of JCPDS, and the tungsten oxide of the present invention may be viewed as the W₁₈O₄₉-type tungsten oxide.

TABLE 1
The comparison of the W₁₈O₄₉ lattice plane and
corresponding 2θ in JCPDS database and the
measurement result in XRD of the W₁₈O₄₉₋ₓSₓ

| | | 2θ from XRD |
|---|---|---|
| lattice | 2θ from JCPDS | measurement |
| plane | (degree) | (degree) |
| (002) | 13.93 | 13.98 |
| ( 3̅04) | 14.48 | 14.54 |
| (010) | 23.48 | 23.72 |
| (103) | 23.78 | 24.28 |
| ( 4̅04) | 27.11 | 27.96 |
| (004) | 28.07 | 28.74 |
| (113) | 33.66 | 34.02 |
| (014) | 36.90 | 36.92 |
| (020) | 48.02 | 48.24 |
| (405) | 49.35 | 49.40 |
| (123) | 55.43 | 55.44 |
| (017) | 56.15 | 56.72 |

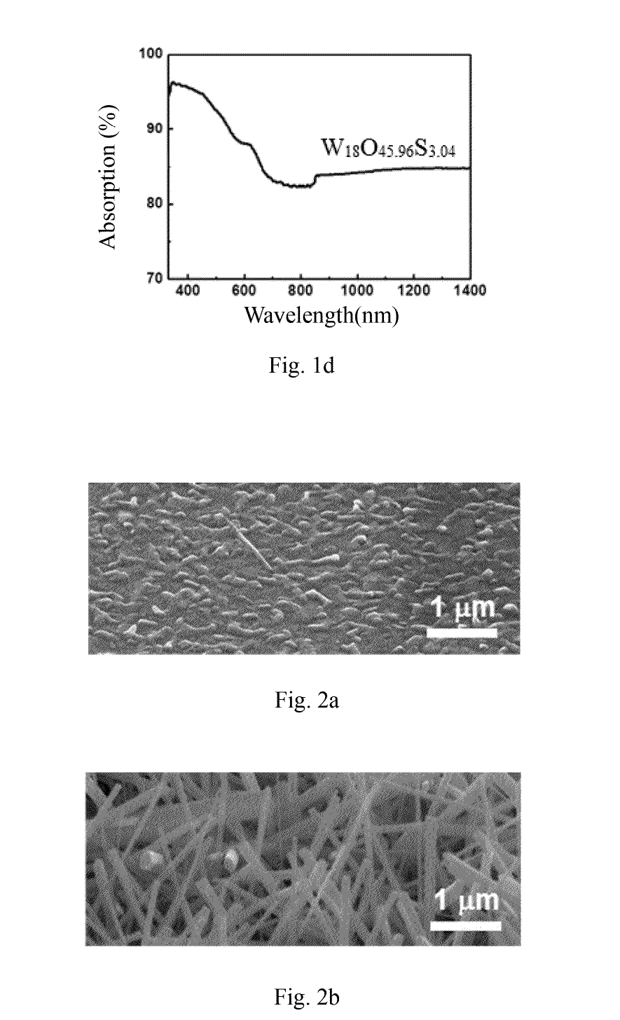

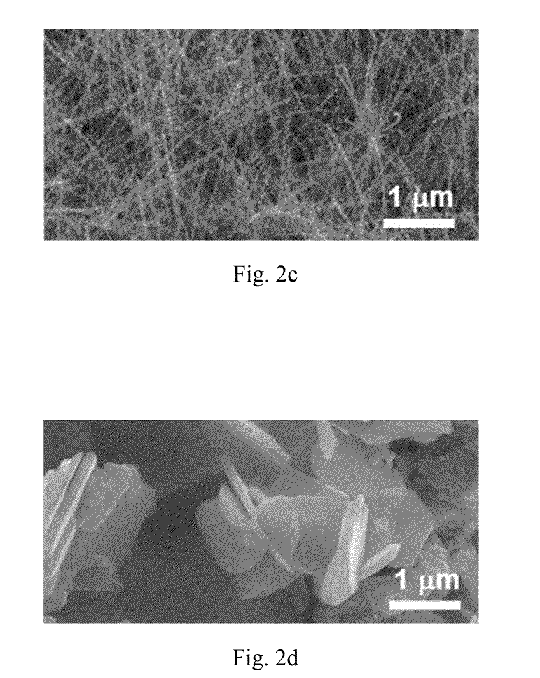

The effects of different factors, such as weight ratio of WS₂ and SnCl₂ in the precursor to W₁₈O₄₉₋ₓSₓ nanomaterial structure are now described. With other process variables fixed, namely substrate temperature=500° C., chamber temperature=700-900° C., and ratio of O₂ and Ar=0.2%, the single variable, the ratio of WS₂ in the precursor, was changed and the W₁₈O₄₉₋ₓSₓ with different structures was then obtained. Refer to FIG. 2a-2d, which are scanning electron microscope (SEM) images showing the W₁₈O₍₄₉₋ₓ₎Sₓ nanostructure of the present invention, using WS₂ as 100%, 66.7%, 40%, and 10% precursors, respectively. FIG. 2a shows the 100-200 nm sheet structure when using the precursor containing 100% WS₂ (only WS₂ in the precursor, no SnCl₂). FIG. 2b shows that, when using the precursor containing 66.7%, more amounts of nanomaterial structures were obtained, where there are most amount of nanorod structure with wider external diameter (100-200 nm) and shorter length (2-5 μm) and fewer amount of thin and long nanowire structure with 10 nm external diameter and 6-10 μm length. FIG. 2c shows the dense nanowire structure with 10 nm external diameter and 3-10 μm length when using the precursor containing 40% WS₂. FIG. 2d shows the plank structure with 1 μm width when using the precursor containing 10% WS₂.

The optical characteristics of the W₁₈O₄₉₋ₓSₓ nanomaterial of the present invention are now described. Regarding light absorption, the measurement method is using a blank glass slide for baseline correction first to prevent the effect of glass slide in reflection and absorption spectrum. The measured transmission of the slide is A_{bs} %=100−Tᵣₐₙₛ %−R_{ef} %, where A_{bs} is the absorption efficiency of the present material, Tᵣₐₙₛ is the transmission of the glass slide, and R_{ef} is the reflection. As shown in FIG. 1d, the measured absorption of W₁₈O_{45.96}S_{3.04}, for example, is about 80% to 95% in the wavelength range 300-1400 nm, and it therefore shows that the W₁₈O₄₉₋ₓSₓ nanomaterial of the present invention is an excellent light absorption material.

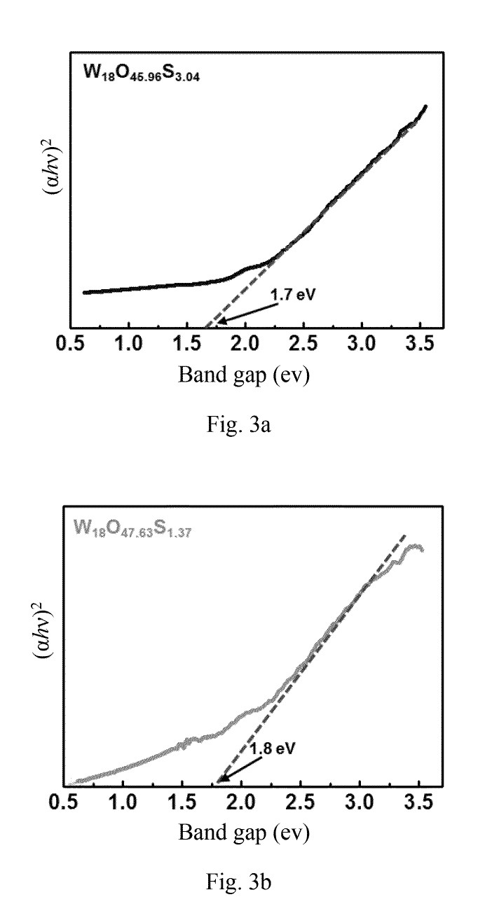

In FIGS. 3a and 3b, the band gap value of the W₁₈O₄₉₋ₓSₓ nanomaterial is further described. FIGS. 3a and 3b are diagrams showing (αhv)²-hv relation of the W₁₈O_{45.96}S_{3.04} and W₁₈O_{47.63}S_{1.37} nanowires of the present invention to calculate the band gap. Utilizing a linear zone in the (αhv)²-hv relation diagrams of the W₁₈O_{45.96}S_{3.04} and W₁₈O_{47.63}S_{1.37} nanowires, the hv value on the X-axis is the band gap value of the W₁₈O_{45.96}S_{3.04} and W₁₈O_{47.63}S_{1.37} nanowires by using the intersection of the tangent line and the Y-axis (α=0), where α, h and v represent absorption coefficient, Plank constant, and frequency, respectively. In FIGS. 3a and 3b, band gap of the W₁₈O_{45.96}S_{3.04} nanowire is 1.7 eV, and band gap of the W₁₈O_{47.63}S_{1.37} nanowire is 1.8 eV. The absorption coefficient α may be obtained by using the formula I=I₀ e^{-αt}, where α is absorption coefficient, t is material thickness (cm), and I and I₀ are intensity of the emitting light and transmitted light. After calculation, the absorption coefficient of the W₁₈O_{45.96}S_{3.04} nanowire is 7.8×10⁴ cm⁻¹, and the absorption coefficient of the W₁₈O_{47.63}S_{1.37} nanowire is 5.5×10⁴ cm⁻¹. Using the above optical analysis (FIGS. 2, 3a and 3b), the W₁₈O₄₉₋ₓSₓ nanomaterial of the present invention has great light absorption, and may have lower band gap by doping sulfur. Further, the W₁₈O₄₉₋ₓSₓ nanomaterial is a semiconductor material and has gas absorption property. Applications in light/gas detectors, semiconductors and solar cells using the W₁₈O₄₉₋ₓSₓ nanomaterial of the present invention are further explained in the following second to fourth embodiments.

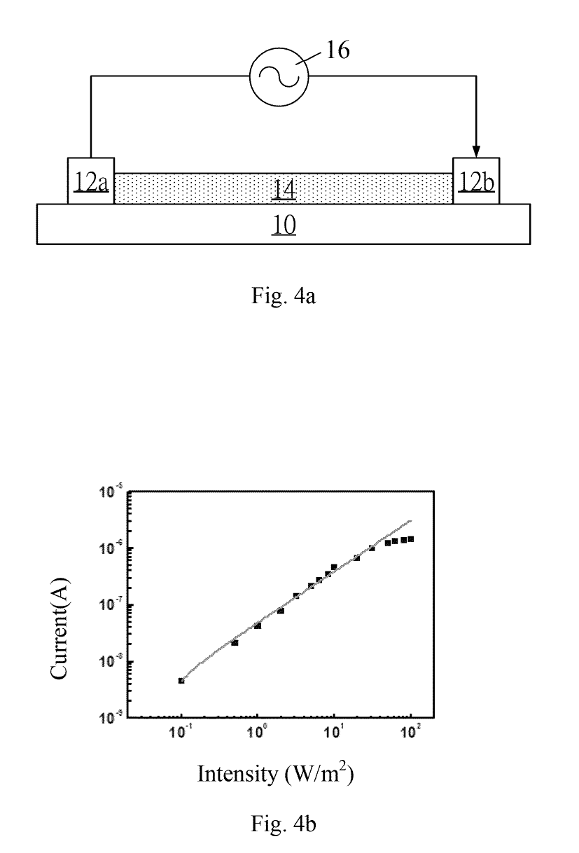

Please refer to FIG. 4a which shows a light sensor according to the second embodiment of the present invention. The light sensor comprises a substrate 10, an electrode unit, a photoelectric conversion unit 14, and a current detecting unit 16. As the process described in the first embodiment, the W₁₈O₄₉₋ₓSₓ nanomaterial is formed on the substrate 10 to be the photoelectric conversion unit 14, and the focused-ion beam (FIB) is used for depositing the electrode unit. The electrode unit comprises a first electrode 12a and a second electrode 12b. The focused-ion beam dissociates the metal gas into metal (such as Pt) according to the depositing position of the first and second electrodes 12a, 12b, and then the metal Pt is deposited to form the first and second electrodes 12a, 12b and electrically connected to the photoelectric conversion unit 14. The photoelectric conversion unit 14 including the W₁₈O₄₉₋ₓSₓ nanomaterial generates light current after light illumination. The current detecting unit 16 is electrically connected to the first electrode 12a and the second electrode 12b, for detecting the light current fabricated by the photoelectric conversion unit 14 passing through the first electrode 12a and the second electrode 12b.

The W₁₈O_{45.96}S_{3.04} nanowire of the present invention is characterized in full spectrum light absorption according to the above analysis and in the second embodiment, the light sensor utilizes the photoelectric conversion unit 14 with W₁₈O_{45.96}S_{3.04} nanowire. The illuminating light is 532 nm green light, and has about 20W/m² intensity. FIG. 4b shows the relation of light intensity and light current when the photoelectric conversion unit in the light sensor of the present invention is illuminated. Here, the photoconductivity gain (G) is used to evaluate the photovoltaic efficiency of the photoelectric conversion unit 14, and defined as the electron amount (Nₑₗ) received by the electrode unit in a period and divided by the photon amount (Nₚₕ) received by the photoelectric conversion unit 14 in a period. It is also represented by G=Nₑₗ/Nₚₕ, and may be further simplified as

$$G = \frac{{I}_{p h / q}}{( P / hv )} ,$$

wherein Iₚₕ is the light current, q is the elementary charge, P is the light intensity, h is the Plank constant, and v is the light frequency. After calculation, the light sensor using the W₁₈O_{45.96}S_{3.04} nanomaterial as the photoelectric conversion unit 14 has a photoconductivity gain about 10⁷.

The photoelectric conversion unit 14 comprising W₁₈O₄₉₋ₓSₓ nanomaterial of the light sensor in the second embodiment 1 also has the characteristic of gas absorption; therefore, the light sensor in the second embodiment may also be used as a gas detector. Here, the resistance value of the photoelectric conversion unit 14 changes after absorbing gas and may be used for detecting gas. In the case of detecting NO₂, the photoelectric conversion unit 14 comprising the W₁₈O₄₉₋ₓSₓ nanomaterial is an n-type semiconductor. After absorbing NO₂, an oxidative gas with electron affinity higher than O₂, the space charge of the sulfur-doped tungsten oxide may be increased with electrons captured NO₂ and the resistance of the photoelectric conversion unit 14 is thus increased. The current detecting unit 16 may be used for monitoring the light current passing through the first electrode 12a and the second electrode 12b to determine whether the gas has been detected by the photoelectric conversion unit 14.

In the third embodiment of the present invention, a metal-oxide-semiconductor field-effect transistor comprises a substrate 10, an oxide layer 11, a source electrode S, a drain electrode D, and a semiconductor channel layer 13. The oxide layer 11 is an insulation layer formed on the substrate 10, and the source electrode S and the drain electrode D are formed on the oxide layer 11. The semiconductor channel layer 13 is configured on the oxide layer 11 to form a channel between the source electrode S and the drain electrode D, and a gate electrode G is configured on the lower surface of the substrate 10.

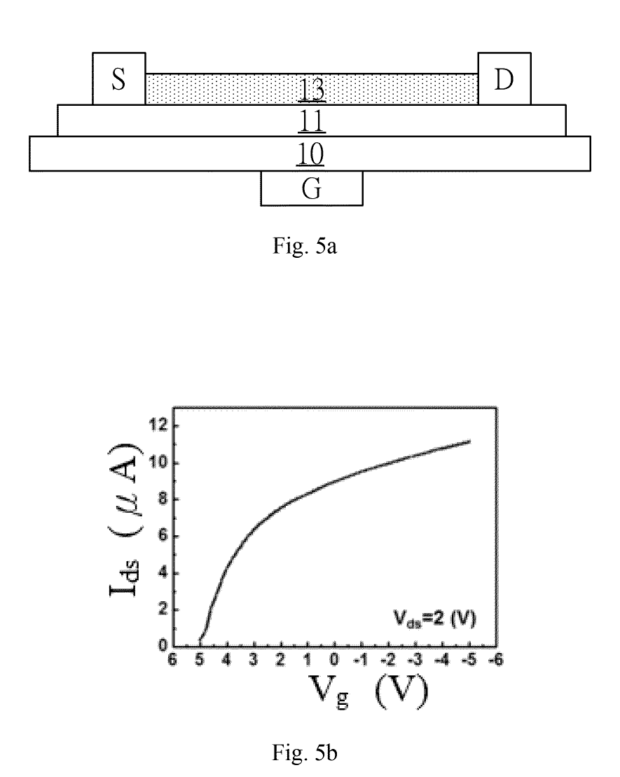

Please refer to FIG. 5a for describing the fabrication process of the MOSFET of the third embodiment. The oxide layer 11 is made of SiO₂. The fabrication process of the semiconductor channel layer 13 includes placing the W₁₈O₄₉₋ₓSₓ nanomaterial into isopropanol (IPA), using ultrasonic shaker to disperse, sucking the IPA having W₁₈O₄₉₋ₓSₓ nanomaterial with pipetman and dripping to the substrate 10, heating to dry the substrate 10, and using the focused-ion beam to deposit metal and connect the source electrode S and the drain electrode D. The voltage value applied to the gate electrode G of the MOSFET can be used to control the conductance of the channel formed between the source electrode S so as to determine the conductivity characteristics of the channel. In the third embodiment, the W₁₈O₄₉₋ₓSₓ nanomaterial is a p-type semiconductor. The conductive channel between the source electrode S and the drain electrode D may be formed and the electron hole with positive voltage may then flow into the drain electrode D from the source electrode S through the channel when a positive voltage is applied to the gate electrode G. FIG. 5b shows the relation of I_{ds}-V_{g} measured in the MOSFET using W₁₈O₄₉₋ₓSₓ according to one embodiment of the present invention.

In the fourth embodiment of the present invention, a solar cell comprises a first substrate 21, a second substrate 22, a light absorption layer 23, and a semiconductor layer 24. A first electrode 211 is configured on the first substrate 21. The light absorption layer 23 comprises W₁₈O₄₉₋ₓSₓ nanomaterial. The semiconductor layer 24 is configured on the light absorption layer 23. Then, a second electrode 222 is configured on the second substrate 22.

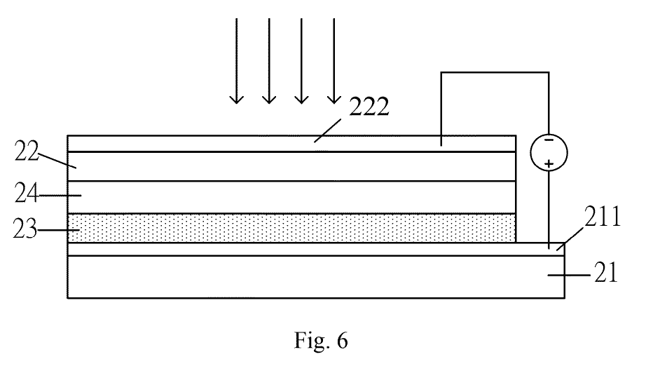

Please refer to FIG. 6 for describing the fabrication process of the solar cell of the fourth embodiment. First, the Pt with thickness 150 nm is deposited as the first electrode 211 on the first substrate 21 by sputtering, and then the W₁₈O₄₉₋ₓSₓ nanomaterial of the resent invention is deposited on the first substrate 21. The W₁₈O₄₉₋ₓSₓ nanomaterial is a p-type semiconductor used as the light absorption layer 23. For forming the PN junction, n-type ZnS or n-type CdS is used as n-type semiconductor layer on the light absorption layer 23. Finally, a transparent conductive layer is formed on the n-type semiconductor layer 24 as the second electrode 222, where the transparent conductive layer is Aluminum doped ZnO with 1 μm thickness. The light absorption layer 23 of the solar cell comprises the sulfur-doped W₁₈O₄₉₋ₓSₓ nanomaterial. The light absorption layer 23 is capable of absorbing the solar light and transform to electric energy (arrow in FIG. 6 represents the illumination direction), and then the voltage difference is formed between the first and second electrodes 211, 222 to generate light current. In this embodiment, the W₁₈O₄₉₋ₓSₓ nanomaterial is a p-type semiconductor and is used as the light absorption layer 23. Furthermore, the W₁₈O₄₉₋ₓSₓ nanomaterial of the present invention may also be provided with properties of an n-type semiconductor by adjusting the process factors. Similarly, for forming the PN junction, when n-type semiconductor W₁₈O₄₉₋ₓSₓ nanomaterial is used as the light absorption layer 23, and the semiconductor layer 24 with the p-type semiconductor material is used as p-type semiconductor layer 24 is assembled to the substrate and electrodes to form the solar cell.

The sulfur-doped W₁₈O₄₉₋ₓSₓ nanomaterial tungsten oxide with nanowire structure in has a minimum external diameter about 10 nm, a high surface-to-volume ratio, a wide light absorption spectrum, a wave length in the range of 300-1400 nm, a light absorption rate about 80% (95% maximum). In the case of W₁₈O_{45.96}S_{3.04} nanowire, it may reach 7.8×10⁴ cm⁻¹ absorption coefficient, and a low band gap 1.7 eV by doping sulfur. The sulfur-doped nanomaterial tungsten oxide of the present invention is provided with great photovoltaic transforming efficiency. Therefore, photoconductivity gain of the fabricated light sensor may reach 10⁷ and is much higher than that (G=4.6×10³) in conventional WO₃ nanomaterial. With the above characteristics, the sulfur-doped nanomaterial tungsten oxide of the present invention may be applied in light/gas detector and solar cell and highly improve the sensor sensitivity and the photovoltaic transforming efficiency of the solar cell.

While the invention can be subject to various modifications and alternative forms, a specific example thereof has been shown in the drawings and is herein described in detail. It should be understood, however, that the invention is not to be limited to the particular form disclosed, but on the contrary, the invention is to cover all modifications, equivalents, and alternatives falling within the spirit and scope of the appended claims.

What is claimed is:

1. A W₁₈O₄₉-type tungsten oxide nanomaterial, having a chemical formula (I):
W₁₈O₍₄₉₋ₓ₎Sₓ (I)
, wherein x ranges from 0.5 to 5.5.

2. The W₁₈O₄₉-type tungsten oxide nanomaterial of claim 1, wherein x ranges from 2 to 4.

3. The W₁₈O₄₉-type tungsten oxide nanomaterial of claim 1, wherein the W₁₈O₄₉-type tungsten oxide nanomaterial is fabricated from a precursor comprising WS₂ by a deposition process after a thermal oxidation reaction.

4. The W₁₈O₄₉-type tungsten oxide nanomaterial of claim 1, wherein the precursor further comprises SnCl₂.

5. The W₁₈O₄₉-type tungsten oxide nanomaterial of claim 1, wherein the W₁₈O₄₉-type tungsten oxide nanomaterial is further doped with Se or Te.

6. The W₁₈O₄₉-type tungsten oxide nanomaterial of claim 1, wherein a structure of the W₁₈O₄₉-type tungsten oxide nanomaterial comprises nanowire, nanorod, nanotube or thin film.

7. A light sensor, comprising:
a substrate;
an electrode unit configured on the substrate and comprising a first electrode and a second electrode;
a photoelectric conversion unit configured on the substrate and electrically connected to the first electrode and the second electrode, wherein the photoelectric conversion unit is configured for generating a light current after being illuminated by a light and comprises a W₁₈O₄₉-type tungsten oxide nanomaterial having a chemical formula (I):
W₁₈O₍₄₉₋ₓ₎Sₓ (I)
, wherein x ranges from 0.5 to 5.5; and
a current detecting unit electrically connected to the first electrode and the second electrode and configured for detecting the light current passing through the first electrode and the second electrode.

8. The light sensor of claim 7, wherein x ranges from 2 to 4.

9. The light sensor of claim 7, wherein the W₁₈O₄₉-type tungsten oxide nanomaterial is further doped with Se or Te.

10. The light sensor of claim 7, wherein the photoelectric conversion unit is configured for absorbing a gas to generate a resistance change, and the current detecting unit is configured for detecting the resistance change of the photoelectric conversion unit relying on the light current passing through the first electrode and the second electrode.

11. A metal-oxide-semiconductor field-effect transistor, comprising:
a substrate;
an oxide layer, formed on the substrate;
a source/drain electrode, formed on the oxide layer;
a semiconductor channel layer configured on the oxide layer to form a channel between the source/drain electrodes, the channel comprises a W₁₈O₄₉-type tungsten oxide nanomaterial having a chemical formula (I):
W₁₈O₍₄₉₋ₓ₎Sₓ (I)
, wherein x ranges from 0.5 to 5.5; and
a gate electrode, configured on the lower surface of the substrate.

12. The metal-oxide-semiconductor field-effect transistor of claim 11, wherein x ranges from 2 to 4.

13. The metal-oxide-semiconductor field-effect transistor of claim 11, wherein the W₁₈O₄₉-type tungsten oxide nanomaterial is further doped with Se or Te.

14. A solar cell, comprising:
a first substrate, having a first electrode;
a second substrate, having a second electrode;
a light absorption layer, located between the first substrate and the second substrate, wherein the light absorption layer comprises a W₁₈O₄₉-type tungsten oxide nanomaterial having a chemical formula (I):
W₁₈O₍₄₉₋ₓ₎Sₓ (I)
, wherein x ranges from 0.5 to 5.5; and
a semiconductor layer, located between the light absorption layer and the second substrate.

15. The solar cell of claim 14, wherein x ranges from 2 to 4.

16. The solar cell of claim 14, wherein the W₁₈O₄₉-type tungsten oxide nanomaterial is further doped with Se or Te.
